(19) United States
(12) Patent Application Publication
(10) Pub. No.: US 2026/0011680 A1
(43) Pub. Date: Jan. 8, 2026

(54) COLLET FOR DIE ATTACHING AND DIE ATTACHING APPARATUS INCLUDING THE SAME

(71) Applicant: SAMSUNG ELECTRONICS CO., LTD., Suwon-si (KR)

(72) Inventor: Sangjin LEE, Suwon-si (KR)

(21) Appl. No.: 19/067,070

(22) Filed: Feb. 28, 2025

(30) Foreign Application Priority Data
Jul. 8, 2024 (KR) 10-2024-0089456

(51) Int. Cl. H01L 23/00

(52) U.S. Cl. CPC H01L 24/75; H01L 2224/75318; H01L 2224/75983; H01L 2224/75984; H01L 2924/40

(57) ABSTRACT

A collet for die attaching includes a first portion, a second portion and a third portion. The first portion includes a plate portion including a first through hole extending therethrough and having first and second surfaces opposite to each other in a vertical direction, and a protrusion portion on the second surface of the plate portion and protruding downwardly in the vertical direction. The second portion is under the first portion, and has first and second surfaces opposite to each other in the vertical direction and includes a second through hole extending therethrough and overlapping the protrusion portion of the first portion in the vertical direction. The third portion is between the first and second portions, and contacts the second surface of the plate portion and the first surface of the second portion.

### PRIORITY STATEMENT

This application claims priority under 35 U.S.C. § 119 to Korean Patent Application No. 10-2024-0089456 filed on Jul. 8, 2024 in the Korean Intellectual Property Office (KIPO), the contents of which are herein incorporated by reference in their entirety.

### FIELD

Example embodiments relate to a collet for die attaching and a die attaching apparatus including the same.

### BACKGROUND

An adhesion film may be coated on a first surface of a die, and a second surface of the die may be compressed using a die attaching apparatus so that the die may be bonded to a substrate. If a uniform pressure is not applied to the die, a void may be generated between the adhesion film and an upper surface of the substrate.

### SUMMARY

Example embodiments provide a collet for die attaching having enhanced characteristics.

Example embodiments provide a die attaching apparatus having enhanced characteristics.

According to example embodiments, there is provided a collet for die attaching. The collet may include a first portion, a second portion and a third portion. The first portion may include a plate portion including a first through hole extending therethrough and having first and second surfaces opposite to each other in a vertical direction, and a protrusion portion on the second surface of the plate portion and protruding downwardly in the vertical direction. The second portion may be under the first portion, and may have first and second surfaces opposite to each other in the vertical direction and include a second through hole extending therethrough and overlapping the protrusion portion of the first portion in the vertical direction. The third portion may be between the first and second portions, and may contact the second surface of the plate portion and the first surface of the second portion.

According to example embodiments, there is provided a collet for die attaching. The collet may include a first portion, a second portion and a third portion. The first portion may include a first through hole extending therethrough and may have first and second surfaces opposite to each other in a vertical direction. The second portion may be under the first portion, and may have first and second surfaces opposite to each other in the vertical direction and include a second through hole extending therethrough. The third portion may be between the first and second portions, and may contact the second surface of the first portion and the first surface of the second portion. When the first portion is pressed downwardly, the third portion may be compressed so that a portion of the first portion may move into the second through hole and the second surface of the first portion and the first surface of the second portion may contact each other.

According to example embodiments, there is provided a die attaching apparatus. The die attaching apparatus may include a head, a shank and a collet. The shank may contact an upper surface of the head. The collet may contact a lower surface of the head. The collet may include a first portion, a second portion and a third portion. The first portion may include a plate portion including a first through hole extending therethrough and having first and second surfaces opposite to each other in a vertical direction, and a protrusion portion on the second surface of the plate portion and protruding downwardly in the vertical direction. The second portion may be under the first portion. The second portion may have first and second surfaces opposite to each other in the vertical direction, and may include a second through hole extending therethrough and overlapping the protrusion portion of the first portion in the vertical direction. The third portion may be between the first and second portions, and may contact the second surface of the plate portion and the first surface of the second portion.

When a die with an adhesion film coated thereon is bonded to an upper surface of a substrate using a die attaching apparatus including a collet in accordance with example embodiments, uniform pressure may be applied to the die, so that no void may be generated between the adhesion film and the upper surface of the substrate.

### BRIEF DESCRIPTION OF THE DRAWINGS

Example embodiments will be more clearly understood from the following detailed description taken in conjunction with the accompanying drawings. FIGS. 1 to 8 represent non-limiting, example embodiments as described herein.

FIG. 1 is a cross-sectional view illustrating a die attaching apparatus in accordance with example embodiments.

FIG. 2 is a plan view illustrating a first portion of a collet of the die attaching apparatus.

FIG. 3 is a bottom view of a second portion of the collet.

FIGS. 4 and 5 are cross-sectional views illustrating an operation of the die attaching apparatus in accordance with example embodiments.

FIG. 6 is a bottom view illustrating the second portion of the collet of the die attaching apparatus when a die is bonded to a PCB by the die attaching apparatus.

FIGS. 7 and 8 are drawings illustrating the collet of the die attaching apparatus in accordance with example embodiments.

### DETAILED DESCRIPTION

Hereinafter, example embodiments will be explained in detail with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

Two directions among horizontal directions that are substantially parallel to an upper surface of a head of a die attaching apparatus, a semiconductor chip or a substrate may be referred to as first and second directions D1 and D2, and a vertical direction that is substantially perpendicular to the upper surface of the head of the die attaching apparatus, the semiconductor chip or the substrate may be referred to as a third direction D3. In example embodiments, the first and second directions D1 and D2 may be substantially perpendicular to each other.

Each of the first to third directions D1, D2 and D3 may include not only a direction shown in the drawings but also a direction reverse thereto.

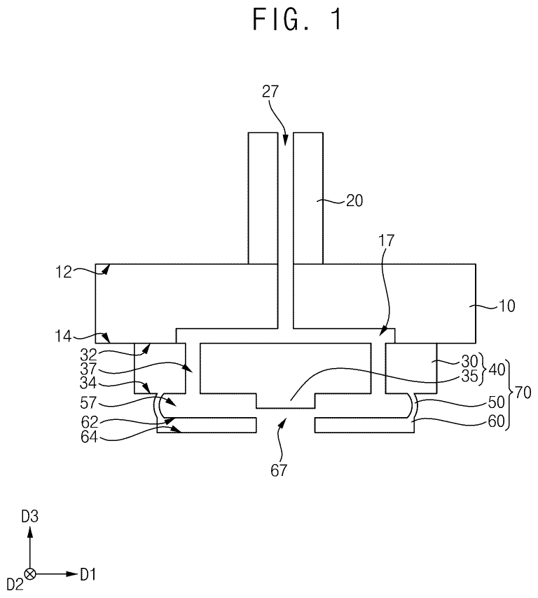

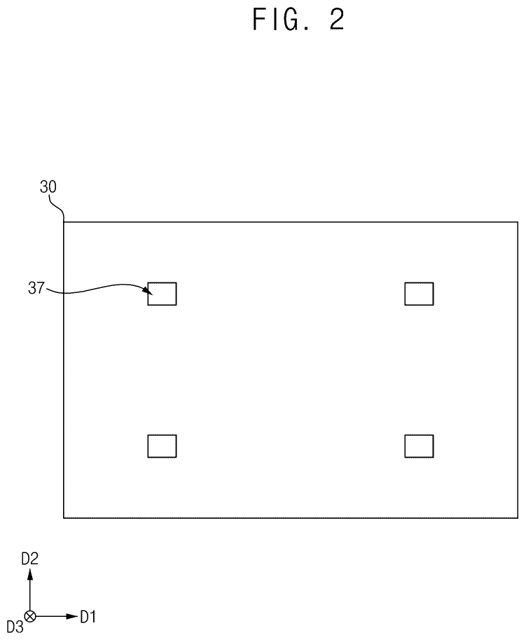

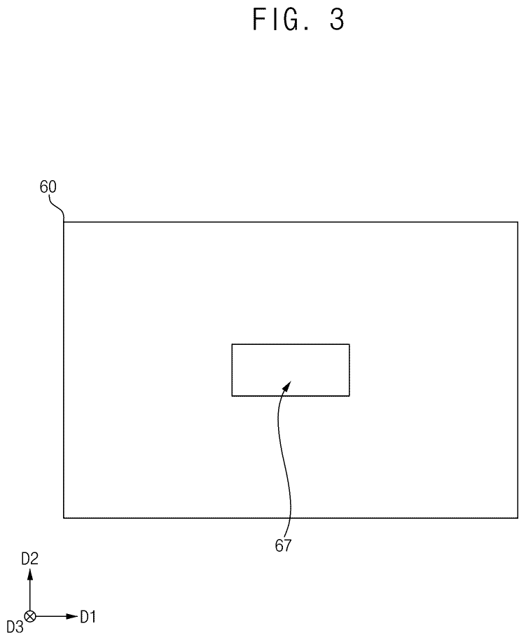

FIG. 1 is a cross-sectional view illustrating a die attaching apparatus in accordance with example embodiments. FIG. 2 is a plan view illustrating a first portion of a collet of the die attaching apparatus, and FIG. 3 is a bottom view of a second portion of the collet.

Referring to FIGS. 1 to 3, the die attaching apparatus may include a head 10, a shank 20 and a collet 70.

The die attaching apparatus may further include a driving portion that may be connected to the shank 20 for moving the head 10 and the collet 70, and a vacuum formation module for forming vacuum in order to absorb a die or a semiconductor chip, which may be connected to the shank 20 or the head 10.

In example embodiments, the die attaching apparatus may be used for picking up a die or a semiconductor chip into which a wafer may be singulated by a sawing process, and placing and bonding the die or the semiconductor chip onto a package substrate, a PCB, another die or another semiconductor chip.

The driving portion of the die attaching apparatus may move the head 10 and the collet 70. For example, the driving portion may move the head 10 and the collet 70 in an X direction, a Y direction and a Z direction (e.g., in the first direction D1, the second direction D2, and the third direction D3).

The head 10 may have a shape of, e.g., a rectangular plate. The head 10 may have first and second surfaces 12 and 14 (e.g., upper and lower surfaces) opposite to each other in the third direction D3, and a recess 17 may be formed at a lower portion of the head 10.

The shank 20 may be disposed on the head 10, and may contact an upper surface of the head 10. In example embodiments, the shank 20 may have a shape of, e.g., a circular pillar or a cylinder. A first through hole or channel 27 extending in the third direction D3 to be connected (e.g., fluidly connected) to the recess 17 may be disposed at central portions of the shank 20 and the head 10.

However, shapes and positions of the recess 17 and the first through hole 27 are not limited to those of FIG. 1, and each of the recess 17 and the first through hole 27 may have other shapes and/or positions.

The collet 70 may include a first portion 40, a third portion 50 and a second portion 60 sequentially stacked in the third direction D3 downwardly from the second surface 14 of the head 10.

In example embodiments, the first portion 40 of the collet 70 may include a plate or plate portion 30 having a shape of, e.g., a rectangular plate, and a protrusion or protrusion portion 35 beneath the plate portion 30 and having a planar area smaller than that of the plate portion 30.

The plate portion 30 may include first and second surfaces 32 and 34 (e.g., upper and lower surfaces) opposite to each other in the third direction D3. The first surface 32 of the plate portion 30 may contact the second surface 14 of the head 10.

A second through hole or channel 37 may extend through the plate portion 30, and may be connected to the recess 17 at the lower portion of the head 10. The second through hole 37 may have a shape of, e.g., a rectangle or a circle in a plan view, however, the inventive concepts are not limited thereto. In example embodiments, a plurality of second through holes 37 may be spaced apart from each other in each of the first and second directions D1 and D2, and FIG. 2 shows four second through holes 37 as an example.

The protrusion portion 35 may contact the second surface 34 of the plate portion 30, and may protrude in the third direction D3 downwardly from the second surface 34 of the plate portion 30. The protrusion portion 35 may have a shape of, e.g., a rectangle or a circle in a plan view, however, the inventive concepts are not limited thereto. In example embodiments, the protrusion portion 35 may overlap a central portion of the plate portion 30 in a plan view. The protrusion portion 35 may vertically overlap a central portion of the plate portion 30. In example embodiments, the plate portion 30 and the protrusion portion 35 may be integrally formed or monolithic.

The second portion 60 of the collet 70 may have a shape of, e.g., a rectangular plate, and may include first and second surfaces 62 and 64 (e.g., upper and lower surfaces) opposite to each other in the third direction D3. The first surface 62 of the second portion 60 of the collet 70 may face the second surface 34 of the first portion 40 of the collet 70 in the third direction D3.

A third through hole 67 may extend through the second portion 60 of the collet 70, and may overlap (e.g., vertically overlap) the protrusion portion 35 of the first portion 40 of the collet 70 in the third direction D3. The third through hole 67 may have a shape substantially the same as that of the protrusion portion 35 of the first portion 40 of the collet 70, that is, for example, a shape of a rectangle or a circle.

In example embodiments, a planar area of the third through hole 67 may be substantially the same as or slightly greater than a planar area of the protrusion portion 35. In example embodiments, a thickness in the third direction D3 of the second portion 60 of the collet 70 may be substantially the same as or slightly smaller than a thickness in the third direction D3 of the protrusion portion 35. Thus, a depth in the third direction D3 of the third through hole 67 may be substantially the same as or slightly smaller than that of the protrusion portion 35.

The third portion 50 of the collet 70 may be disposed between and contact the second surface 34 of the plate portion 30 of the first portion 40 of the collet 70 and the first surface 62 of the second portion 60 of the collet 70. In example embodiments, the third portion 50 of the collet 70 may have a shape of, e.g., a rectangular ring or a circular ring, and may have a convex shape outwardly. The third portion 50 of the collet 70 may contact an edge of the plate 30 of the first portion 40 of the collet 70 and an edge of the second portion 60 of the collet 70. Thus, the third portion 50 of the collet 70 may surround the second through holes 37 extending through the plate portion 30 of the first portion 40 of the collet 70 and the third through hole 67 extending through the second portion 60 of the collet 70, in a plan view.

In example embodiments, the collet 70 may include an elastic material, e.g., rubber.

The die attaching apparatus may further include a heater at the head 10.

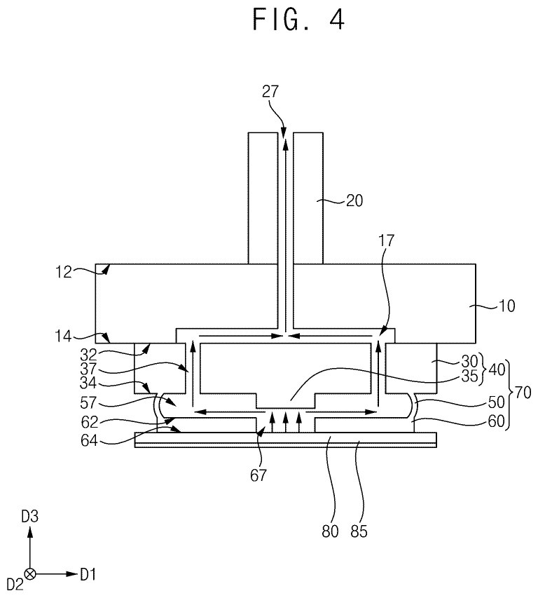

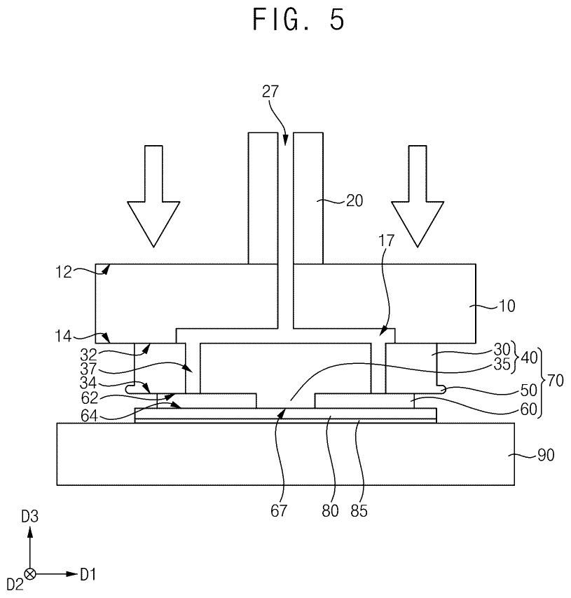

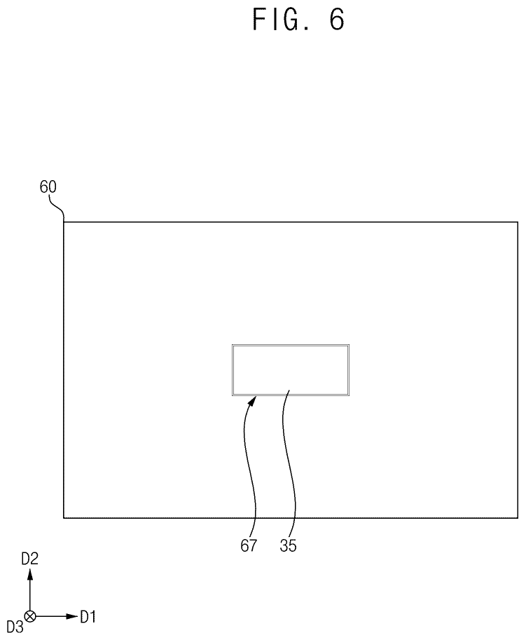

FIGS. 4 and 5 are cross-sectional views illustrating an operation of the die attaching apparatus in accordance with example embodiments, and FIG. 6 is a bottom view illustrating the second portion of the collet of the die attaching apparatus when a die is bonded to a PCB by the die attaching apparatus.

Referring to FIG. 4, the die attaching apparatus may absorb a die 80 or a semiconductor chip 80 to which an adhesion film 85, e.g., a die attach film (DAF) or a non-conductive film (NCF) is attached, and pick up the die 80 or the semiconductor chip 80.

A vacuum formation module of the die attaching apparatus may absorb the die 80 or the semiconductor chip 80 through the first through hole 27 extending through the shank 20 and the head 10, the second through hole 37 extending through the plate portion 30 of the first portion 40 of the collet 70 and connected to the recess 17 at the lower portion of the head 10, a space between the first to third portions 40, 60 and 50 of the collet 70, and the third through hole 67 extending through the second portion 60 of the collet 70.

Referring to FIGS. 5 and 6, the driving portion of the die attaching apparatus may press the head 10 and the collet 70 via the shank 20 downwardly in the third direction D3.

Thus, the third portion 50 of the collet 70 may be pressed (e.g., compressed) so that the second surface 34 of the plate portion 30 of the first portion 40 of the collet 70 may contact the first surface 62 of the second portion 60 of the collet 70, and the protrusion portion 35 of the first portion 40 of the collet 70 may be inserted into the third through hole 67 extending through the second portion 60 of the collet 70 to contact and press an upper surface of the die 80. The third portion 50 of the collet 70 may be deformable and/or resilient.

During the pressing of the driving portion, the protrusion portion 35 of the first portion 40 of the collet 70 may contact and press the upper surface of the die 80 in addition to the second portion 60 of the collet 70, so that all portions of the upper surface of the die 80 except for edge portion of the die 80 may be directly pressed by the collet 70.

That is, during the pressing of the driving portion, the space between the first to third portions 40, 60 and 50 of the collet 70 may be extinguished (see, e.g., the space 57 in FIG. 4), the third through hole 67 extending through the second portion 60 of the collet 70 may be filled with the protrusion portion 35, so that the upper surface of the die 80 may not be exposed by the first to third through holes 27, 37 and 67.

Thus, the adhesion film 85 attached to a lower surface of the die 80 may be well attached to an upper surface of a substrate 90, e.g., a package substrate or a PCB with no void between the adhesion film 85 and the substrate 90.

If the collet 70 includes only the plate portion 30 of the first portion 40 without the second and third portions 60 and 50, and a cavity for absorbing the die 80 and the second through hole 37 extending through the plate portion 30 and connected to the cavity are formed in the plate portion 30, during the pressing of the driving portion, an upper surface of a portion of the die 80 overlapping in the third direction D3 the cavity or the second through hole 37 in the plate portion 30 may not contact the plate portion 30 to not to be directly pressed, so that a void may be generated between the adhesion film 85 and the substrate 90.

However, in example embodiments, the upper surface of the die 80 may be directly and entirely pressed by the second portion 60 and the protrusion portion 35 of the collet 70, so that no void may be generated between the adhesion film 85 and the substrate 90 and the die 80 may be well attached to the substrate 90.

After the die 80 is bonded to the substrate 90 through the adhesion film 85, air may be blown through the first and second through holes 27 and 37 so that the collet 70 may be separated from the die 80. The third portion 50 of the collet 70 may return (e.g., expand) to its original shape.

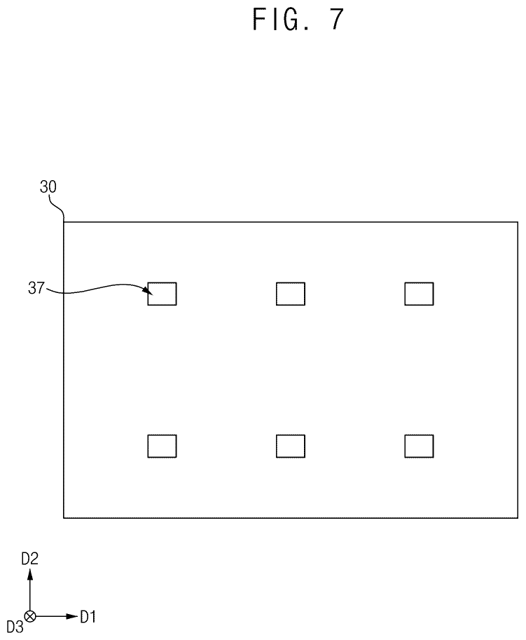

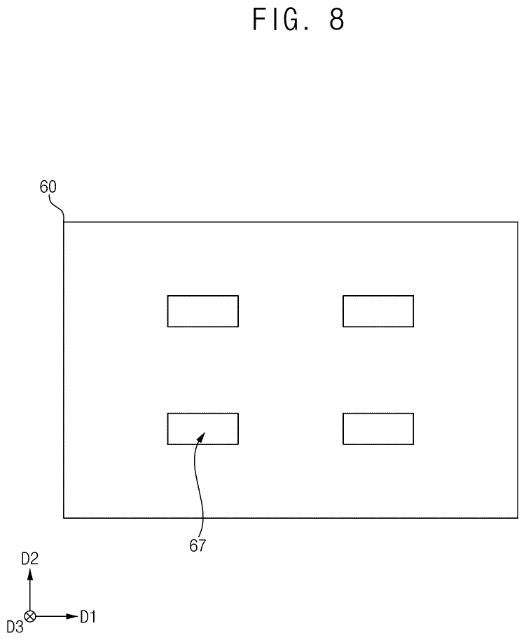

FIGS. 7 and 8 are drawings illustrating the collet of the die attaching apparatus in accordance with example embodiments. FIG. 7 is a plan view of the first portion of the collet, which may correspond to FIG. 2, and FIG. 8 is a bottom view of the second portion of the collet, which may correspond to FIG. 3.

Referring to FIG. 7, unlike that of FIG. 2, the plate portion 30 of the first portion 40 of the collet 70 may include six second through holes 37 extending through the plate portion 30.

However, the inventive concepts are not limited thereto, and the plate portion 30 may include a plurality of second through holes 37.

Referring to FIG. 8, unlike that of FIG. 3, the second portion 60 of the collet 70 may include four third through holes 67.

However, the inventive concepts are not limited thereto, and the second portion 60 of the collet 70 may include a plurality of third through holes 67.

In example embodiments, the first portion 40 of the collet 70 may include a plurality of protrusion portions 35 overlapping (e.g., vertically overlapping) the third through holes 67 of the second portion 60 of the collet 70 in the third direction D3, and each of the protrusion portions 35 may have a shape substantially the same as that of the third through hole 67 and a planar area substantially the same as or slightly smaller than that of the third through hole 67.

In a plan view, the third through holes 67 may not overlap the second through holes 37 in the third direction D3, and each of the third through holes 67 may be disposed between neighboring ones of the second through holes 37.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present inventive concepts. Accordingly, all such modifications are intended to be included within the scope of example embodiments as defined in the claims.

What is claimed is:

1. A collet for die attaching, comprising:
a first portion including:
a plate portion including a first through hole extending therethrough, the plate portion having first and second surfaces opposite to each other in a vertical direction; and
a protrusion portion on the second surface of the plate portion and protruding downwardly in the vertical direction;
a second portion under the first portion, the second portion having first and second surfaces opposite to each other in the vertical direction, and the second portion including a second through hole extending therethrough and overlapping the protrusion portion of the first portion in the vertical direction; and
a third portion between the first and second portions, the third portion contacting the second surface of the plate portion and the first surface of the second portion.

2. The collet for die attaching of claim 1, wherein the protrusion portion of the first portion and the second through hole have substantially the same shape in a plan view.

3. The collet for die attaching of claim 1, wherein each of the protrusion portion of the first portion and the second through hole has a shape of a rectangle or a circle in a plan view.

4. The collet for die attaching of claim 1, wherein a planar area of the protrusion portion of the first portion is substantially the same as or smaller than a planar area of the second through hole.

5. The collet for die attaching of claim 1, wherein a thickness in the vertical direction of the protrusion portion of the first portion is substantially the same as or smaller than a thickness in the vertical direction of the second portion.

6. The collet for die attaching of claim 1, wherein the first portion further includes a plurality of protrusion portions spaced apart from each other in a horizontal direction, the protrusion portion being one of the plurality of protrusion portions, and
wherein the second portion further includes a plurality of second through holes spaced apart from each other in the horizontal direction, the second through hole being one of the plurality of second through holes.

7. The collet for die attaching of claim 1, wherein the first through hole does not overlap the second through hole in the vertical direction.

8. The collet for die attaching of claim 1, wherein the third portion surrounds the first through hole in a plan view.

9. The collet for die attaching of claim 1, wherein the third portion has a shape of a rectangular ring or a circular ring.

10. The collet for die attaching of claim 1, wherein a space defined by the second surface of the first portion, the first surface of the second portion and the third portion is connected to the first and second through holes.

11. The collet for die attaching of claim 1, wherein each of the first to third portions includes rubber.

12. A collet for die attaching, comprising:
a first portion including a first through hole extending therethrough, the first portion having first and second surfaces opposite to each other in a vertical direction;
a second portion under the first portion, the second portion having first and second surfaces opposite to each other in the vertical direction, and the second portion including a second through hole extending therethrough; and
a third portion between the first and second portions, the third portion contacting the second surface of the first portion and the first surface of the second portion,
wherein when the first portion is pressed downwardly, the third portion is compressed so that a portion of the first portion moves into the second through hole and the second surface of the first portion and the first surface of the second portion contact each other.

13. The collet for die attaching of claim 12, wherein a space defined by the second surface of the first portion, the first surface of the second portion and the third portion is fluidly connected to the first and second through holes.

14. The collet for die attaching of claim 12, wherein a portion of the first portion and the second through hole have substantially the same shape in a plan view, and wherein a planar area of the portion of the first portion is substantially the same as a planar area of the second through hole.

15. The collet for die attaching of claim 12, wherein the first through hole does not overlap the second through hole in the vertical direction.

16. The collet for die attaching of claim 1, wherein the third portion surrounds the first through hole in a plan view.

17. The collet for die attaching of claim 1, wherein each of the first to third portions includes rubber.

18. A die attaching apparatus, comprising:
a head;
a shank contacting an upper surface of the head; and
a collet contacting a lower surface of the head, the collet including:
a first portion including:
a plate portion including a first through hole extending therethrough, the plate portion having first and second surfaces opposite to each other in a vertical direction; and
a protrusion portion on the second surface of the plate portion and protruding downwardly in the vertical direction;
a second portion under the first portion, the second portion having first and second surfaces opposite to each other in the vertical direction, and the second portion including a second through hole extending therethrough and overlapping the protrusion portion of the first portion in the vertical direction; and
a third portion between the first and second portions, the third portion contacting the second surface of the plate portion and the first surface of the second portion.

19. The die attaching apparatus of claim 18, wherein the protrusion portion of the first portion and the second through hole have substantially the same shape in a plan view, and wherein a planar area of the protrusion portion of the first portion is substantially the same as or smaller than a planar area of the second through hole.

20. The die attaching apparatus of claim 19, wherein a thickness in the vertical direction of the protrusion portion of the first portion is substantially the same as or smaller than a thickness in the vertical direction of the second portion.
